(19) United States
(12) Patent Application Publication
(10) Pub. No.: US 2026/0173924 A1
(43) Pub. Date: Jun. 18, 2026

(54) THREE-DIMENSIONAL PACKAGE WITHOUT THROUGH-SILICON VIAS

(71) Applicant: Zero ASIC Corporation, Lexington, MA (US)

(72) Inventors: Andreas Olofsson, Lexington, MA (US); Lizabeth Keser, San Diego, CA (US)

(21) Appl. No.: 19/043,105

(22) Filed: Jan. 31, 2025

Related U.S. Application Data
(60) Provisional application No. 63/735,657, filed on Dec. 18, 2024.

(51) Int. Cl. H01L 23/498; H01L 23/31; H01L 23/367; H01L 23/538; H01L 25/07

(52) U.S. Cl. CPC H10W 70/65; H10W 40/22; H10W 70/611; H10W 74/131; H10W 90/00; H10W 90/701

(57) ABSTRACT

A three-dimensional (3D) packaging technique couples stacked integrated circuit die in a 3D package without using through-silicon vias (TSVs). The 3D packaging technique reduces processing complexity, reduces the cost of manufacture and packaging, and may be implemented in semiconductor manufacturing technologies that do not include TSV technology. In an embodiment, the technique uses through-mold vias (TMVs), which have reduced processing complexity as compared to TSVs. In an embodiment, the 3D packaging technique does not use fan-out packaging. The reduced processing complexity increases yield, thereby reducing cost. In addition, associated equipment, processes, and materials are also lower in cost than those for using TSVs, thereby further reducing cost. The reduced processing complexity also facilitates installation and qualification of the 3D packaging technique in manufacturing lines, thus increasing availability of the 3D packaging technique as compared to 3D packaging techniques that use TSVs.

### CROSS-REFERENCE TO RELATED APPLICATION(S)

This application claims benefit under 35 U.S.C. § 119 of U.S. Provisional Application No. 63/735,657, entitled “Three-Dimensional Package Without Through-Silicon Vias,” filed on Dec. 18, 2024, naming Andreas Olofsson and Lizabeth Keser as inventors, which application is hereby incorporated by reference.

### BACKGROUND

### Field of the Invention

This application relates to design, manufacture, and packaging of integrated circuit products.

### Description of the Related Art

Advanced integrated circuit packaging technologies (e.g. Chip-on-Wafer-on-Substrate (CoWoS) platform by Taiwan Semiconductor Manufacturing Company (TSMC) or Foveros technology by Intel Corporation) use through-silicon vias (TSVs) to couple stacked integrated circuit die in a three-dimensional (3D) package. In general, TSV technology is expensive, is not available in all manufacturing process nodes, and has limited availability in manufacturing process nodes that do offer TSVs. For example, TSVs may only be available for processing of passive silicon interposers like CoWoS and not for processing of active silicon integrated circuit die. Accordingly, improved techniques for stacking and packaging integrated circuits are desired.

### SUMMARY OF EMBODIMENTS OF THE INVENTION

In at least one embodiment, an integrated circuit product includes an active semiconductor device including a plurality of die interfaces arranged in an N-by-M tile map on a front side of the active semiconductor device, where N and M are integers of at least one. The integrated circuit product includes a conductive pillar coupled to the active semiconductor device. The conductive pillar is disposed on the front side of the active semiconductor device and extends vertically from the front side of the active semiconductor device. The integrated circuit product includes an integrated circuit die coupled to the front side of the active semiconductor device. The integrated circuit die is disposed face-to-face with the active semiconductor device and is disposed laterally from the conductive pillar with respect to the front side of the active semiconductor device. The integrated circuit product includes encapsulant disposed on the active semiconductor device. A portion of the encapsulant is disposed between the conductive pillar and the integrated circuit die. The conductive pillar is disposed on a lane between adjacent die interfaces of the plurality of die interfaces and the conductive pillar is adjacent to the integrated circuit die.

The integrated circuit die may be coupled to a first die interface of the plurality of die interfaces and the integrated circuit product may further include a second integrated circuit die disposed face-to-face with the active semiconductor device, disposed laterally from the integrated circuit die with respect to the front side of the active semiconductor device, and coupled to a second die interface of the plurality of die interfaces. The integrated circuit product may further include at least one additional conductive pillar disposed on another lane of the N-by-M tile map and coupled to the active semiconductor device. The integrated circuit die and the second integrated circuit die may be disposed on adjacent tiles of the N-by-M tile map and the conductive pillar may be disposed between the integrated circuit die and the second integrated circuit die. The conductive pillar may be disposed between the active semiconductor device and a redistribution layer. The integrated circuit die and the active semiconductor device may not include any through-silicon vias.

The integrated circuit product may include a redistribution layer disposed on the encapsulant and overlapping the integrated circuit die and the conductive pillar. The redistribution layer may include a conductor coupled to the conductive pillar and may include dielectric material. The conductor may be coupled to the conductive pillar at a first surface of the redistribution layer and may be coupled to a conductive bump at a second surface of the redistribution layer. The second surface may be distant from the conductive pillar, the integrated circuit die, and the encapsulant. The integrated circuit product may include a heat spreader disposed on the redistribution layer. The heat spreader may include a grid of apertures. The integrated circuit product may include at least one integrated circuit module coupled to the conductive pillar and disposed on the redistribution layer in an aperture of the grid of apertures. The integrated circuit product may include a packaged circuit subsystem disposed adjacent to a back side of the integrated circuit die. The packaged circuit subsystem may include a vertical conductive structure coupled to the conductive pillar. The integrated circuit product may include a through-mold via disposed adjacent to a stack of devices. The stack of devices includes the active semiconductor device and the integrated circuit die. The integrated circuit product may include a redistribution layer including dielectric material and conductive traces coupled to the conductive pillar and the through-mold via and a packaged integrated circuit device adjacent to a back side of the active semiconductor device and coupled to the through-mold via and the redistribution layer by way of the through-mold via. A first exposed conductor portion of the through-mold via may be coupled to the redistribution layer. The integrated circuit product may be packaged and have a first width equal to a second width of the active semiconductor device. The active semiconductor device may include a network-on-chip and the plurality of die interfaces may be coupled to the network-on-chip.

In at least one embodiment, a method of manufacturing an integrated circuit product includes forming a conductive pillar on a front side of an active semiconductor device. The method includes attaching a first integrated circuit die to the front side of the active semiconductor device. The first integrated circuit die is disposed face-to-face with the active semiconductor device and is disposed laterally from the conductive pillar with respect to the front side of the active semiconductor device. The method includes encapsulating the conductive pillar and the first integrated circuit die using encapsulant. The conductive pillar is formed on a lane separating adjacent die interfaces of a plurality of die interfaces arranged in an N-by-M tile map of a surface of the active semiconductor device, where N and M are integers of at least one. The method may include attaching a second integrated circuit die to the front side of the active semiconductor device. The conductive pillar may be between the first integrated circuit die and the second integrated circuit die. The first integrated circuit die may be attached to a first die interface of the plurality of die interfaces and the second integrated circuit die may be attached to a second die interface of the plurality of die interfaces.

The method may include exposing an end surface of the conductive pillar and forming a redistribution layer on the encapsulant and an exposed end surface of the conductive pillar. The redistribution layer may include dielectric material and may include a conductor coupled to the conductive pillar. In an embodiment, the first integrated circuit die, the second integrated circuit die, and the active semiconductor device do not include any through-silicon vias. The method may include attaching a heat spreader disposed on the redistribution layer. The heat spreader may include a grid of apertures. The method may include attaching an integrated circuit module to the conductor, the integrated circuit module being disposed on the redistribution layer in an aperture of the grid of apertures. The method may include forming a conductive bump on a surface of the redistribution layer and coupled to the conductive pillar. The method may include singulating the integrated circuit product. The method may include attaching a packaged integrated circuit product to the conductive bump. The method may include exposing the conductive pillar and forming a through-mold via disposed adjacent to a stack including the active semiconductor device, the first integrated circuit die, and the second integrated circuit die. The method may include forming a redistribution layer including dielectric material and including conductive traces coupled to the conductive pillar and the through-mold via. The first integrated circuit die, the second integrated circuit die, and the active semiconductor device may not include any through-silicon vias. The method may include attaching a packaged integrated circuit device to a back side of the active semiconductor device and coupled to the through-mold via and the redistribution layer by way of the through-mold via. The method may include increasing a surface area of a back side of the active semiconductor device. The method may include selectively exposing through-silicon vias in the active semiconductor device according to a target packaging configuration.

In at least one embodiment, an integrated circuit product includes a packaged module including an active semiconductor device, a plurality of integrated circuit die coupled to the active semiconductor device using a corresponding plurality of integrated circuit die interfaces, and a plurality of conductive pillars coupled to the active semiconductor device and disposed on a front side of the active semiconductor device. The plurality of integrated circuit die interfaces are arranged in an N-by-M tile map on the front side of the active semiconductor device. N and M are integers of at least one, and the plurality of conductive pillars are disposed in lanes between tiles of the N-by-M tile map. The integrated circuit product may include a package-on-package. The package-on-package may include a plurality of connectors disposed to align with the lanes between tiles of the N-by-M tile map. The package-on-package may include through-mold vias and a plurality of heterogeneous devices disposed laterally with respect to the front side of the active semiconductor device and disposed between a first redistribution layer and a second redistribution layer. The package-on-package may include vertical conductive structures on a first surface of the first redistribution layer. The vertical conductive structures may be aligned with the plurality of connectors. A second surface of the first redistribution layer is closer to the plurality of heterogeneous devices than the first surface.

### BRIEF DESCRIPTION OF THE DRAWINGS

The present invention may be better understood, and its numerous objects, features, and advantages made apparent to those skilled in the art by referencing the accompanying drawings.

FIG. 1A illustrates an exemplary composable chiplet platform including a library of chiplets having standard sizes and a fabric device.

FIG. 1B illustrates a cross-sectional view of an exemplary 3D packaged integrated circuit product designed using the composable chiplet platform of FIG. 1A and including a fabric device and chiplets that do not use TSVs.

FIGS. 2A, 2C, and 2E illustrate cross-sectional views of various 3D packaged integrated circuit products including chiplets and a fabric device that do not use TSVs.

FIGS. 2B, 2D, and 2F illustrate cross-sectional views of various 3D packaged integrated circuit products including chiplets and a fabric device that use TSVs.

FIG. 3 illustrates a cross-sectional view of an exemplary 3D packaged integrated circuit product including a fabric device and chiplets that do not use TSVs.

FIGS. 4, 5, 6, 7, and 8 illustrate an exemplary process flow for manufacturing the 3D packaged integrated circuit product of FIG. 3.

FIG. 9 illustrates a cross-sectional view of a 3D packaged integrated circuit device of FIG. 3 including a heat spreader.

FIG. 10 illustrates a cross-sectional view of a 3D packaged integrated circuit device of FIG. 3 including a heat spreader and air-cooled heat sink.

FIG. 11 illustrates a cross-sectional view of a 3D packaged integrated circuit device of FIG. 3 including a fabric device having a nonplanar back side for use with liquid cooling.

FIG. 12 illustrates a cross-sectional view of a 3D packaged integrated circuit device of FIG. 3 including chiplets coupled to a fabric device using conductive pillar microbumps and including power module integrated circuits vertically coupled to the fabric device using through-mold vias.

FIG. 13 illustrates a cross-sectional view of a 3D packaged integrated circuit device of FIG. 3 including chiplets coupled to a fabric device using hybrid bonds and including power module integrated circuits vertically coupled to the fabric device using through-mold vias.

FIG. 14 illustrates a cross-sectional view of a 3D packaged integrated circuit device of FIG. 3 including chiplets coupled to a fabric device using hybrid bonds and including power module integrated circuits disposed within apertures of a heat spreader.

FIG. 15 illustrates a plan view of a 3D packaged integrated circuit device of FIG. 14 including power modules disposed within apertures of a heat spreader.

FIG. 16 illustrates a cross-sectional view of a 3D packaged integrated circuit device of FIG. 3 including a subsystem to be coupled to the front side of a fabric device having a non-planar back side in a package-on-package configuration.

FIG. 17 illustrates a cross-sectional view of a 3D packaged integrated circuit device of FIG. 3 including a subsystem coupled to a back side of the fabric device in a package-on-package configuration.

FIG. 18 illustrates a cross-sectional view of an exemplary 3D packaged integrated circuit product including a fabric device and chiplets that do not use TSVs.

The use of the same reference symbols in different drawings indicates similar or identical items.

### DETAILED DESCRIPTION

A three-dimensional (3D) packaging technique couples stacked integrated circuit die in a 3D package without using through-silicon vias (TSVs). The 3D packaging technique reduces processing complexity, reduces the cost of manufacture and packaging, and may be implemented in semiconductor manufacturing technologies that do not include TSV technology. In an embodiment, the technique uses through-mold vias (TMVs), which have reduced processing complexity as compared to TSVs. In an embodiment, the 3D packaging technique does not use fan-out packaging. The reduced processing complexity increases yield, thereby reducing cost. In addition, associated equipment, processes, and materials are also lower in cost than those for using TSVs, thereby further reducing cost. The reduced processing complexity also facilitates installation and qualification of the 3D packaging technique in manufacturing lines, thus increasing availability of the 3D packaging technique as compared to 3D packaging techniques that use TSVs. The 3D packaging technique is suited for packaging systems of integrated circuit devices for low power application (e.g., fifth generation (5G) or sixth generation (6G) cellular network telecommunications, Internet of Things, Automotive or Advanced Driver Assistance Systems, or embedded applications).

In an embodiment of the 3D packaging technique, rather than using TSVs that are etched and filled in an integrated circuit device, a 3D package is formed by plating conductive (e.g., copper) pillars directly onto a semiconductor wafer (i.e., wafer) in lanes between the integrated circuit die. Since conductive pillars have finer pitch than conductive bumps, in an embodiment, copper pillars are fabricated on top of Under Bump Metallization (UBM) using photolithography and deposition processes and are capped with tin-silver to form electronic interconnect. In an embodiment, the pillars are at least 50 μm high. However, other methods or materials for forming conductive pillars may be used. In an embodiment, the conductive pillars are used to connect an integrated circuit die on a wafer to a substrate for the delivery of power, signals, or ground. Another integrated circuit die, e.g., a small, thin integrated circuit die (i.e., a chiplet), is then placed on the wafer in between conductive pillars that provide 3D interconnection to the integrated circuit die of the wafer. For example, a 10 mm×10 mm integrated circuit die accommodates an array of 4×4 chiplets, where each chiplet is 2 mm×2 mm in size. Interconnects between the chiplet and an integrated circuit device formed using the wafer could be made in a variety of ways depending on the interconnect pitch. For example, solder, conductive pillar micro-bumps (e.g., copper microbumps), or hybrid bonds (e.g., copper-to-copper hybrid bonds) may be used.

In an embodiment, the chiplets are placed 100 μm apart, which leaves space for conductive pillars (e.g., copper pillars that are 50 μm in diameter and 50 μm tall) to be disposed on the integrated circuit device of the wafer and disposed in between the chiplets. After chip attach of the chiplets to the wafer, the chiplets are encapsulated with mold material, and grinding of the mold material exposes the conductive pillars and, in some cases, exposes the back side of the chiplets (e.g., exposes the silicon surface). After grinding the mold material, a redistribution layer (RDL) is formed on the mold material and the exposed conductive pillars.

In general, an RDL is a layer including dielectric material and conductors formed on an integrated circuit die and used to route electrical connections between contact pads on the integrated circuit die and a location of a package contact (e.g., conductive bumps or balls). Forming an RDL may include depositing and patterning conductive layers to transform an existing input/output layout into a pattern that satisfies the requirements of a solder bump design. Redistribution layers typically have thicknesses substantially greater than the thicknesses of typical dielectric and conductive layers formed on an integrated circuit die. For example, a typical conductive layer in an integrated circuit is less than 1 μm thick and corresponding dielectric layers are also less than 1 μm thick. However, conductive layers in an exemplary RDL are at least 2 μm thick and corresponding dielectric layers are at least 5 μm thick. In another embodiment, the dielectric layers are at least 15 μm thick. Dielectric layers used to form a redistribution layer are typically organic materials (e.g., benzocyclobutene (BCB) or polyimide) since they exert less stress on conductive layer or other structures on the wafer, although in some embodiments, inorganic materials (e.g., silicon nitride, oxynitride, or silicon oxide) are used. The materials used may be selected based on dielectric constant, elongation to failure, coefficient of thermal expansion, Young's modulus, moisture absorption, or other parameter. Conductive layers used to form the RDL may include aluminum, copper, or other suitable materials.

In an embodiment, a dielectric layer is deposited on the mold material, exposed conductive pillars, and chiplet back sides and then, conductive traces are formed (e.g., plated). After plating, another dielectric layer is deposited. Then, solder interconnects are plated to form an array of bumps on the RDL. The RDL couples the conductive pillars to final solder interconnects, which may be coupled to a printed circuit board (PCB). The wafer is then singulated into individual units and those units are attached to a substrate or PCB.

In at least one manufacturing process, use of conductive pillars for power delivery is efficient for small chiplets (e.g., 2 mm×2 mm) and is less efficient for chiplets having larger sizes (e.g., greater than 2 mm×2 mm). In some embodiments, a target manufacturing process limits the power distribution such that sufficient power is distributed for only small chiplets and only small chiplets may be used. In other target manufacturing processes the power distribution is sufficient for larger-sized chiplets and larger-sized chiplets may be used.

The size of the conductive pillar depends on the pitch between the chiplets attached to the wafer. In an embodiment 100 μm pitch between a landing pattern (i.e., electrical interfaces) for 2 mm×2 mm chiplets allows for a 50 μm diameter conductive pillar and sufficient clearance for a tool to place the chiplets between conductive pillars during chip attach. In an embodiment, the height-to-diameter aspect ratio of the conductive pillar is at least 2:1, when formed, but could be higher. In contrast, conductive bumps or other vertical conductive structures formed on a wafer typically have an aspect ratio of 1:1. The height of the conductive pillar determines the height of the chiplets. For example, if 100 μm pitch conductive pillars having diameters of 50 μm can only be 100 μm high and need to be exposed via grinding to 90 μm high, then the back side of the chiplet will also be at most 90 μm high. A 50 μm diameter pillar can deliver an efficient amount of power to a 2 mm×2 mm chiplet. Smaller pillars can deliver sufficient power to smaller chiplets. In some embodiments, increasing the scale of the pillar improves power delivery to chiplets larger than 2 mm×2 mm but may be an inefficient use of area on the surface of the integrated circuit die. In embodiments having thermal dissipation issues with thin chiplets, a thermal interface material (TIM) and heat sink or heat spreader are used. In some embodiments, a heat sink is added to a heat spreader using a second TIM.

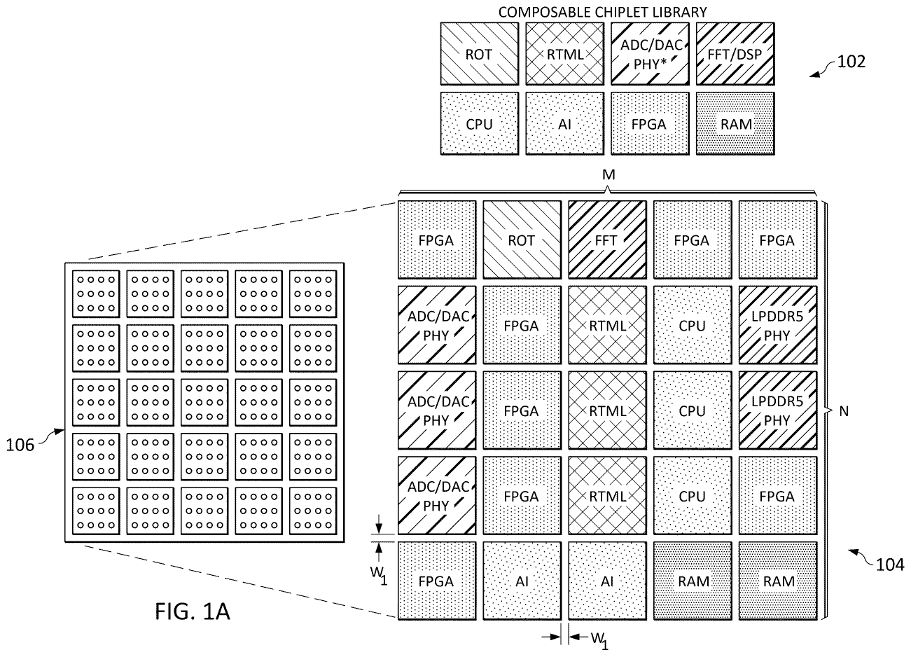

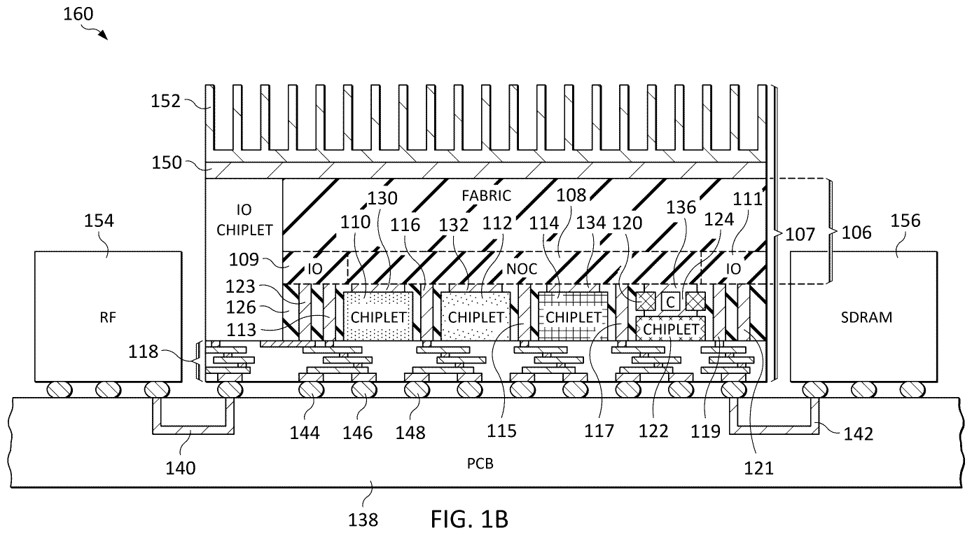

Referring to FIGS. 1A and 1B, an exemplary modular chiplet system enables various integrated circuit systems to be created from a relatively small set of chiplet types (e.g., Central Processing Unit (CPU), Field Programmable Gate Array (FPGA), Artificial Intelligence (AI) processor, Digital Signal Processor (DSP), Fast Fourier Transform (FFT) processor, Real Time Machine Learning (RTML) processor, Root of Trust (ROT) processor, Analog-to-Digital Converter (ADC)/Digital-to-Analog Converter (DAC) Physical Interface (PHY), Random Access Memory (RAM), Low-Power Double Data Rate 5 (LPDDR5) PHY), defined by composable chiplet library and a multi-interface fabric device. The modular chiplet system includes a fabric device that provides services to the 3D assembled chiplets. For example, embodiments of a fabric device include a built-in network-on-chip, 3D chiplet interfaces for connecting to chiplets stacked with the fabric device, which is an active semiconductor device formed using active devices (e.g., diodes or transistors) formed using a semiconductor substrate. Embodiments of the fabric device also include power delivery networks, clocking, system management, and general-purpose I/O. In an embodiment, chiplet library 102 includes mechanically and electrically interchangeable chiplets that can be connected to fabric device 106 at one or more sites of a tile map having N×M sites, where N and M are integers greater than or equal to one. Arrangement 104 illustrates various chiplets arranged in a 5×5 tile map for coupling to corresponding chiplet interfaces of fabric device 106.

In an embodiment, the modular chiplet system implements a shared memory architecture that allows the chiplets to communicate with each other using read/write transactions that are routed by the network-on-chip. The network-on-chip also enables communication between different resources of the fabric device. In some embodiments, bidirectional, low-latency 3D communication links connect the chiplets to the network-on-chip. The bidirectional link serializes memory access transactions across the 3D interface. The bidirectional link can be source synchronous or include clock and data recovery. In some embodiments, a parallel source synchronous data bus is used to improve energy efficiency. In addition, the network-on-chip routes power and ground to the chiplets. A chiplet-based system-in-package designed using the modular chiplet system is programmable using memory mapped addressing. An exemplary modular chiplet system is described in U.S. patent application Ser. No. 18/771,693, entitled “Modular Chiplet System,” filed on Jul. 12, 2024, naming Andreas Olofsson as inventor, which application is hereby incorporated by reference.

In at least one embodiment of an integrated circuit product, fabric device 106 includes network-on-chip 108 and Input/Output (I/O) circuits 109 and 111. Network-on-chip 108 is coupled to chiplets 110, 112, 114, and 120 via chiplet interfaces and vertical interconnect 130, 132, 134, and 136, respectively (e.g., conductive pillars, conductive microbumps, or other suitable conductive structure known in the art). The face of fabric device 106 (i.e., the surface at which the active devices are formed) is facing the faces of chiplets 110, 112, 114, and 120. In an embodiment, chiplet 122 is stacked on chiplet 120 and coupled to network-on-chip 108 using TSVs (e.g., TSV 124). Mold material 126 is applied to chiplets 110, 112, 114, 120, and 122, vertical interconnect 130, 132, 134, and 136, and conductive pillars (e.g., conductive pillars 113, 115, 116, 117, 119, 121 and 123) disposed on fabric device 106 (e.g., on I/O circuits 109 and 111 and network-on-chip 108) between chiplets or adjacent to a chiplet. In at least one embodiment, conductive pillars disposed between chiplets (e.g., conductive pillars 115, 116, and 117) are aligned with lanes between sites of the N×M tile map of chiplet interfaces and other conductive pillars (e.g., conductive pillars 113, 119, 121 and 123) are aligned with lanes at the periphery of the N×M tile map of chiplet interfaces. In an embodiment, vertical lanes and horizontal lanes between tiles have a width w₁, although in other embodiments, lanes between tiles have different widths. In an embodiment, vertical lanes between tiles have different widths than horizontal lanes between tiles. Mold material 126 is ground to expose the conductive pillars and the back side of the chiplets. In other embodiments, mold material is ground to expose only the conductive pillars and encapsulates the back side of the chiplets. Redistribution layer 118 is formed on the mold materials, exposed conductive pillars, and any exposed chiplet back sides, and includes dielectric material and conductive traces that couple the conductive pillars to solder interconnects (e.g., conductive bumps 144, 146, and 148), which may be coupled to conductors of a printed circuit board 138.

A module including fabric device 106 and encapsulated chiplets 110, 112, 114, 120, and 122 is attached to printed circuit board 138 with the front side of fabric device 106 facing printed circuit board 138 and the back side of chiplets 110, 112, 114, and 122 facing printed circuit board 138. That is, chiplets 110, 112, 114, 120, and 122 are disposed between printed circuit board 138 and fabric device 106. As referred to herein, the front side of a device is the side of a semiconductor die of the device where the active components and circuitry are located. Other vertical conductive structures known in the art are included to couple the conductive pillars to conductive structures on printed circuit board 138. Printed circuit board 138 includes conductors that couple integrated circuit stack 107 to other devices coupled to printed circuit board 138. For example, conductive traces 140 and 142 couple integrated circuit stack 107 to radio frequency transceiver integrated circuit 154 and Synchronous Dynamic Random Access Memory (SDRAM) circuit 156, respectively. In an embodiment, chiplets 110, 112, 114, and 122 are discrete sizes (e.g., 2 mm×2 mm) and are coupled to corresponding chiplet interfaces of fabric device 106 and are spaced from each other by lanes having predetermined width w₁. However, a site, tile or chiplet interface (i.e., chiplet landing pattern or placement site) may or may not be populated. In at least one embodiment, rather than include stacked chiplets that use TSVs, chiplet 122 is excluded and chiplet 120 and other structures of integrated circuit stack 107 do not use any TSVs. In at least one embodiment, TIM 150 is applied to the back side of fabric device 106 heat sink 152 is attached to the back side of the fabric device using.

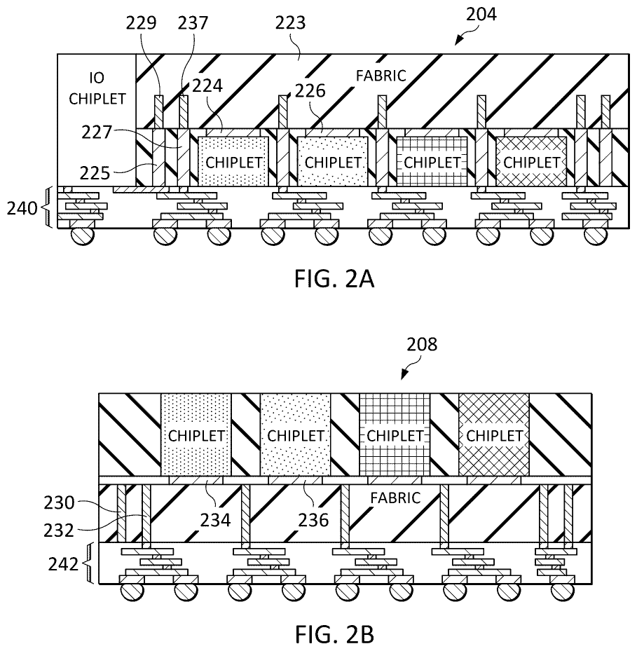

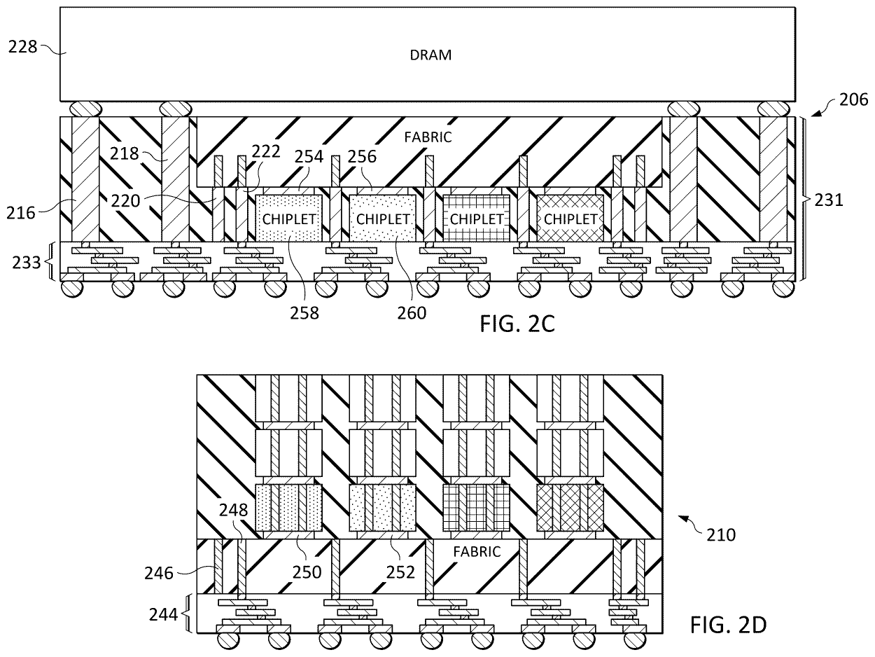

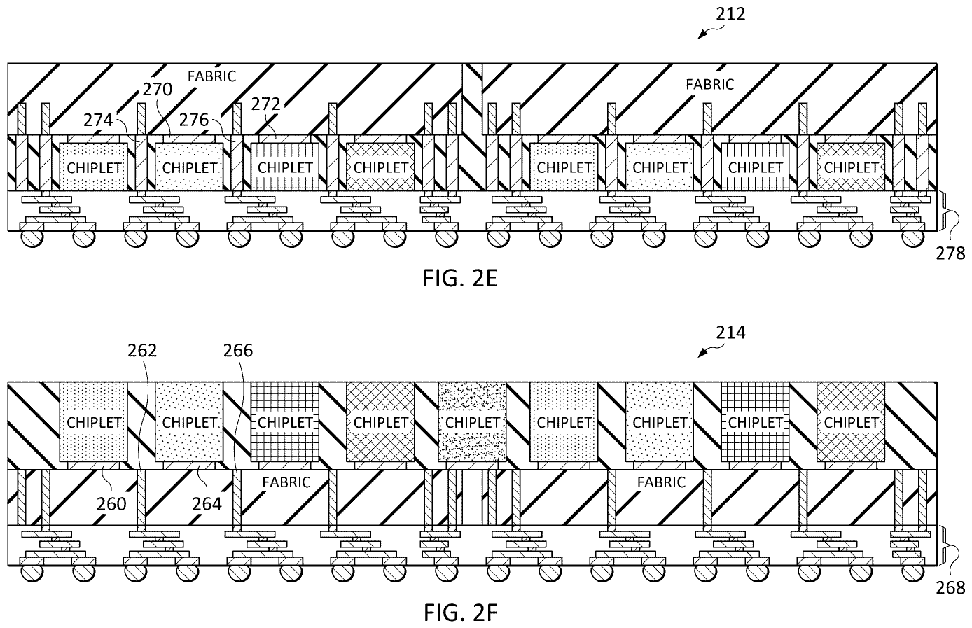

Referring to FIGS. 2A-F, the composable chiplet platform that includes a library of chiplets and fabric devices having chiplet interfaces at one or more sites of a tile map of N×M sites, as described above, can be used to generate integrated circuit products of varying size and complexity that may be packaged using different 3D packaging techniques known in the art, e.g., wafer-level fan out, package-on-package, 3D packaging, wafer-scale packaging, panel scale packaging techniques, or combinations thereof. In some embodiments, a fabric device selected from the library includes TSVs that are selectively exposed and used based on the target product (e.g., based on market, affordability, and package type). In those embodiments, the TSVs of the fabric device are exposed during manufacturing and are used with suitable packaging schemes, e.g., to generate 3D integrated circuit devices 208, 210, and 214. In other embodiments, TSVs are not exposed and are unused (e.g., TSVs 229 and 237 of 3D integrated circuit device 204) or are not included in the fabric device, e.g., packaging schemes of 3D integrated circuit devices 204, 206, and 212 do not use TSVs. In the embodiments where the fabric device does not include TSVs or TSVs are unexposed and are unavailable for use, conductive pillars are formed directly on the fabric device.

Referring to FIG. 2A, in an embodiment, a smaller scale product includes a fabric device that does not use TSVs. Wafer-level fanout is used to couple an I/O chiplet to the fabric device in the packaging scheme of 3D integrated circuit device 204. Chiplets are disposed to face-to-face (i.e., front side-to-front side) with fabric device 223 and are coupled to fabric device 223 using vertical conductors (e.g., conductive structures 224 and 226). Conductive pillars formed on fabric device 223 are encapsulated with the chiplets and are used to provide power, signals, or ground to fabric device 223. For example, conductive pillars 225 and 227, which are coupled to conductors in redistribution layer 240, couple fabric device 223 to input/output terminals. The conductive pillars are formed in lanes between chiplets or at the periphery of a tile map of N×M chiplet interfaces.

FIG. 2B illustrates another embodiment of a smaller scale product. 3D integrated circuit device 208 includes a fabric device that uses TSVs (e.g., TSVs 230 and 232) to provide power, signals, or ground to the front side of the fabric device. In the packaging scheme of 3D integrated circuit device 208, chiplets are attached to the front side of the fabric device by vertical conductors (e.g., vertical conductors 234 and 236). Redistribution layer 242 includes conductors that couple the fabric device to conductive bumps (or other conductors), which couple the TSVs of the fabric device to a printed circuit board, package substrate, or other package.

A larger scale product that does not use TSVs to package an integrated circuit device with a 3D integrated circuit device uses TMVs to couple to a package-on-package (PoP), as illustrated in FIG. 2C. In 3D integrated circuit device 206, packaged Dynamic Random Access Memory (DRAM) 228 is attached to 3D packaged device 231, which includes chiplets (e.g., chiplets 258 and 260) disposed face-to-face with a fabric device, is coupled to the fabric device (e.g., using conductive structures 256 and 256), and encapsulated with the fabric device. Through-mold vias (e.g., TMVs 216 and 218) and conductors in redistribution layer 233 provide power, signals, or ground from conductive bumps to DRAM 228. Conductive pillars (e.g., conductive pillars 220 and 222) are formed on the fabric device in lanes between chiplets or at the periphery of a tile map of N×M chiplet interfaces. Conductors in redistribution layer 233 provide power, signals, or ground from conductive bumps to the fabric device.

Referring to FIG. 2D, in at least one embodiment, a packaging scheme forms 3D integrated circuit device 210 by stacking chiplets, which use TSVs, on a front side of a fabric device. Chiplets are attached to the front side of the fabric device using vertical conductors (e.g., vertical conductors 250 and 252). The fabric device also includes exposed TSVs (e.g., TSVs 246 and 248). The exposed TSVs of the fabric device are used to provide power, signals, or ground vertically through the fabric device to the front side of the fabric device or to the chiplets. The exposed TSVs in the chiplets are used to provide power, signals, or ground vertically through the chiplets to adjacent chiplets in the same stack. The stacks of chiplets are encapsulated with the fabric device. Redistribution layer 244 is formed on the back side of the fabric device and includes conductors that couple the TSVs and the fabric device to other conductors (e.g., conductive bumps) that provide power, signals, or ground from a printed circuit board, package substrate, or other package.

FIG. 2F illustrates another larger-scale product that uses a wafer-scale packaging scheme to form a 3D integrated circuit device. The wafer-scale packaging scheme of 3D integrated circuit device 214 uses vertical conductors (e.g., vertical conductors 260 and 264) to attach chiplets to the front side of a wafer including multiple fabric devices that include exposed TSVs (e.g., TSVs 262 and 266). The chiplets are encapsulated with the fabric device at wafer-level. The exposed TSVs are used to provide power, signals, or ground to the front side of the fabric device. Redistribution layer 268 is formed on the back side of the wafer and includes conductors that couple the TSVs and fabric devices to other conductors (e.g., conductive bumps) that communicate power, signals, or ground between a printed circuit board, package substrate, or other package and the TSVs and fabric devices.

Referring to FIG. 2E, in a panel-scale packaging scheme that does not use TSVs, 3D integrated circuit device 212 includes Known Good Die (KGD) of fabric devices that are reconstituted onto a panel before plating conductive pillars on the fabric devices and attaching chiplets to the fabric devices without any TSVs. The chiplets are disposed face-to-face with corresponding fabric devices using conductive structures (e.g., conductive structures 270 and 272) and encapsulated with the conductive pillars and fabric device before the 3D integrated circuit devices are separated from the panel. Conductive pillars (e.g., conductive pillars 274 and 276) are formed on the fabric device. Conductors in redistribution layer 278 provide power, signals, or ground from conductive bumps to the fabric device by way of the conductive pillars.

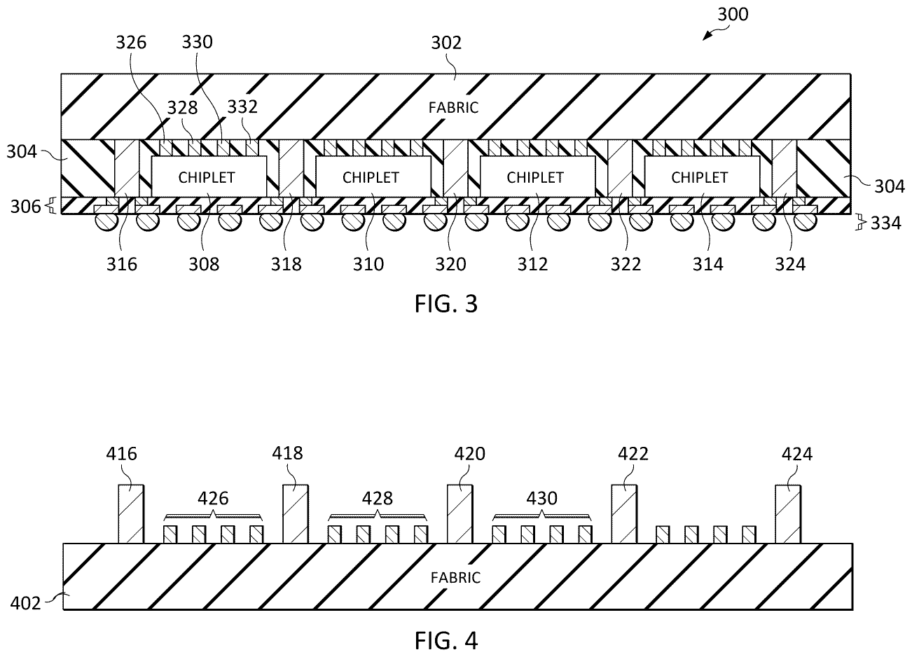

FIG. 3 illustrates an exemplary 3D integrated circuit device that does not use TSVs. In an embodiment, 3D integrated circuit device 300 includes fabric device 302, Fabric device 302 is 10 mm×10 mm and includes N ×M chiplet interface sites. Chiplets 308, 310, 312, and 314 are attached to corresponding chiplet interface sites using vertical interconnect (e.g., vertical conductive interconnect 326, 328, 330, and 332, respectively). Conductive pillars 316, 318, 320, 322, and 324 are formed on fabric device 302 in lanes between chiplet interface sites of the N×M chiplet interface sites or at the periphery of the N×M chiplet interface sites. Mold material 304 encapsulates the chiplets and the conductive pillars and is ground to expose the conductive pillars, and in some embodiments, the back sides of the chiplets. Redistribution layer 306, which includes conductors, is formed on the encapsulated chiplets and exposed surfaces of the conductive pillars. Vertical conductors 334 are formed on the redistribution layer 306 and are coupled to the conductive pillars via conductors in the redistribution layer 306. The chiplets and fabric device 302 are face-to-face. In an embodiment, 3D packaged integrated circuit device 300 is not a fanout package and 3D integrated circuit device 300 has the same width as fabric device 302.

FIGS. 4-8 illustrate at least one embodiment of a process for manufacturing a 3D integrated circuit device 300 of FIG. 3. Referring to FIG. 4, a wafer including fabric device 402 is manufactured using GlobalFoundries 22FDX fully-depleted silicon-on-insulator (FD-SOI) process technology for low power, embedded applications, although other process technologies may be used. Fabric device 402 is 10 mm×10 mm and includes N×M chiplet interface sites. Vertical conductive structures 426, 428, and 430 (e.g., conductive pillars, conductive microbumps, or other suitable conductive structure known the in art) are formed on the front side (i.e., the side of fabric device used to form a network-on-chip or other integrated circuit) of fabric device 402. In an embodiment, fabric device 402 routes power, signals, or ground to the chiplet interface sites.

In an embodiment, conductive pillars 416, 418, 420, and 422 are formed in lanes between chiplet interface sites of the N×M chiplet interface sites of fabric device 402 or at the periphery of the N×M chiplet interface sites of fabric device 402. Conductive pillars 416, 418, 420, and 422 are formed by a wafer-level copper pillar plating process known in the art, which may include patterning photoresist with vias to define features of the copper pillars, forming a copper seed layer at the bottom of voids in the photoresist, wetting the photoresist with suppressor, and entering leveler into the vias during the plating process to create a pillar with a flat top. Leveler, accelerator, and suppressor are organic additives that control plating. Leveler smooths the surface, suppressor inhibits deposition in certain areas to achieve a desired plating profile, and accelerator promotes faster deposition. The photoresist is stripped using known techniques. In at least one embodiment, conductive pillars 416, 418, 420 and 422 have an aspect ratio of at least 2:1, when formed, are at least 100 μm high, which may be determined by the copper pillar plating process, and the conductive pillars have 50 μm diameters, which may be determined by the copper pillar plating process. In at least one embodiment, vertical conductive structures 426, 428, and 430 are formed coupled to a corresponding chiplet interface and may be copper pillar microbumps or copper pads for fusion bonding or hybrid bonding and are formed using known techniques. Spacing between sets of vertical conductive structures (e.g., 100 μm chiplet-to-chiplet spacing) is determined by power delivery requirements. In an embodiment, fanout packaging techniques are not used and the 3D integrated circuit device has the same width as fabric device 402.

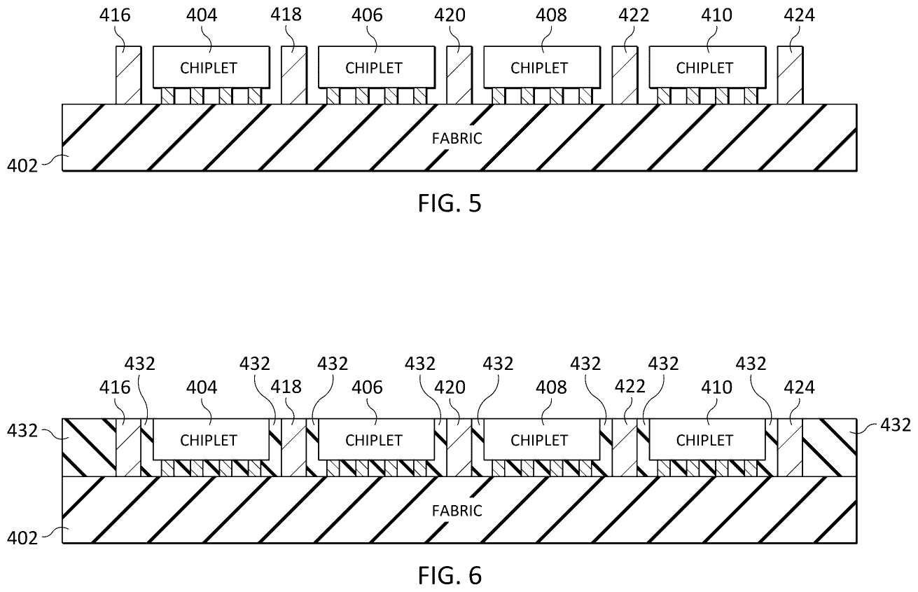

Referring to FIG. 5, in an embodiment, wafer-level chip attach (e.g., fusion bonding, hybrid bonding, or reflow techniques) electrically and mechanically couples 2×2 mm chiplets to the vertical conductive structures on fabric device 402. The conductive pillar height may be greater than or less than the chiplet height. In an embodiment, the conductive pillars and routing in fabric device 402 are capable of delivering ample power to 2×2 mm chiplets, satisfy a lower power requirement for chiplets of 4×4 mm in size, and deliver insufficient power to 8×8 mm chiplets. However, other fabric devices and conductive pillars formed in different manufacturing technologies provide sufficient amounts of power to chiplets of 4×4 mm or larger.

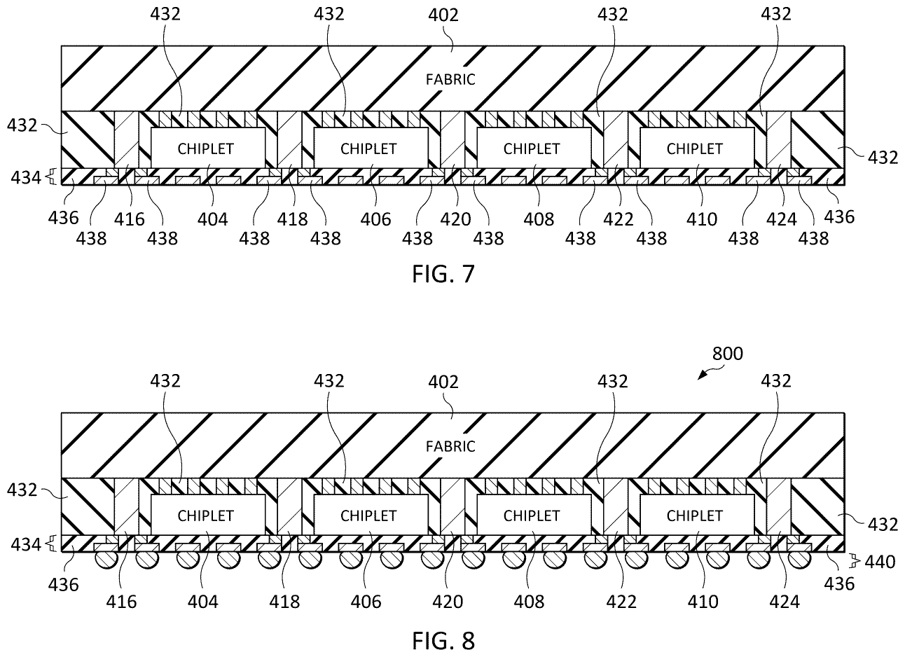

Referring to FIG. 6, in at least one embodiment, mold material 432 is applied at wafer level and mechanically couples the conductive pillars 416, 418, 420, 422, and 424, chiplets 404, 406, 408, and 410, and vertical conductive structures to fabric device 402. Conductive pillars 416, 418, 420, 422, and 424 form through-mold vias in mold material 432. Mold grinding exposes at least the conductive pillars. In an embodiment, mold grinding also exposes the chiplet back sides to improve thermal dissipation. Referring to FIG. 7, redistribution layer 434, which includes dielectric layers 436 and conductive traces 438, is formed on mold materials 432, the exposed surfaces of the copper pillars, and any exposed chiplet back sides, as illustrated in FIG. 7. Referring to FIG. 8, in an embodiment, Controlled Collapse Chip Connections (i.e., C4 bumps) 440 are electroplated onto redistribution layer 434, although other packaging structures for coupling an integrated circuit device to a PCB or substrate may be used. The integrated circuit units 800 are singulated into individual units (e.g., 10 mm×10 mm 3D integrated circuit devices). Those units can be attached to a package substrate or a printed circuit board. The process illustrated in FIGS. 4-8 is exemplary and additional steps or different sequences of steps for manufacturing a 3D packaged integrated circuit system that does not use TSVs consistent with FIG. 3, 2A, 2C or 2F may be used.

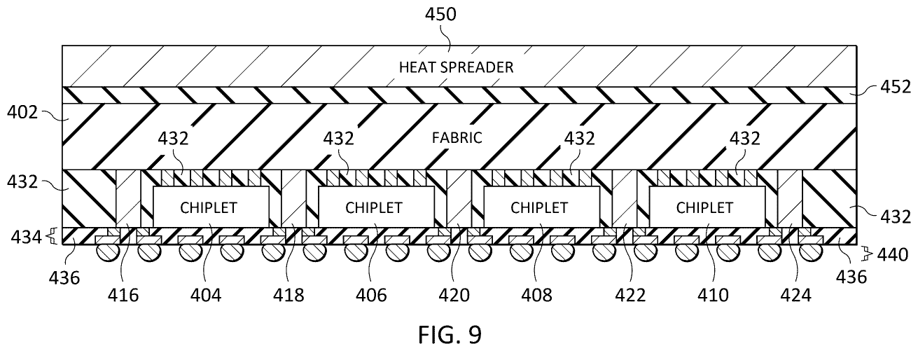

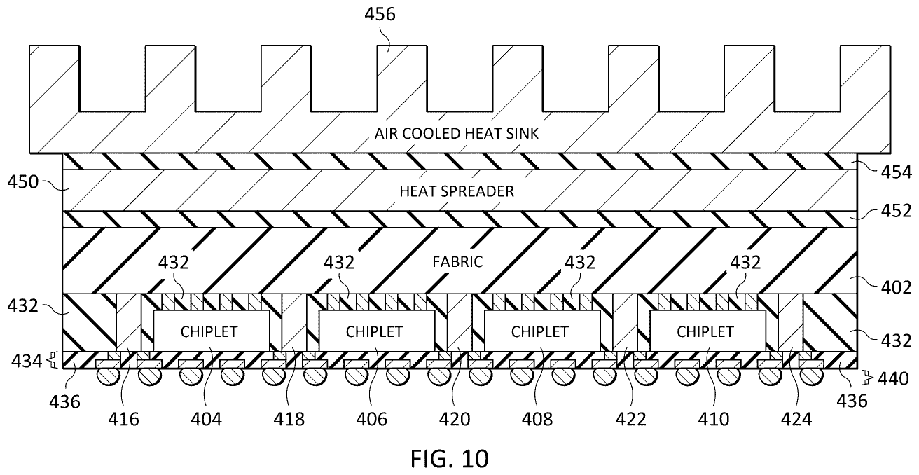

Referring to FIG. 9, in an embodiment, thermal interface material (TIM) 452, which may be a known thermally conductive adhesive or thermal tape, is applied to the back side of fabric device 402 and attaches a first surface of heat spreader 450 to fabric device 402 using known techniques. Referring to FIG. 10, in an embodiment, heat sink 456, which may be used with air cooling techniques, is attached using TIM 454, which may be a thermally conductive adhesive or thermal tape, applied to a second surface of heat spreader 450. In an embodiment, TIM 452 and TIM 454 are different materials (e.g., polymers including conductive material).

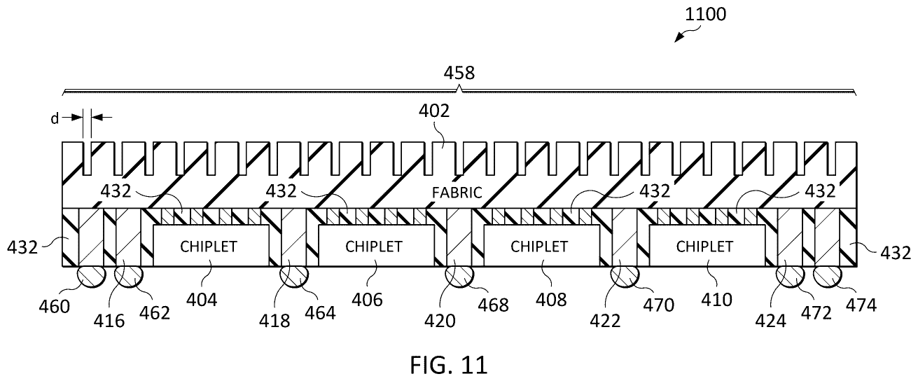

Referring to FIG. 11, at least one embodiment of a 3D integrated circuit device 1100 is cooled using liquid cooling techniques, rather than using a heat spreader or heat sink. Fabric device 402 includes nonplanar back side 458 that has increased surface area as compared to a planar back side to increase the rate of heat transfer by liquid cooling as compared to the rate of transfer by the planar back side. In some embodiments, nonplanar back side 458 is textured, grooved, or includes channels that increase the surface area for contact with a liquid used to cool the 3D integrated circuit device. In at least one embodiment, an etching process is used to create channels in the back side having a width of d and aspect ratio of at least 1:1.

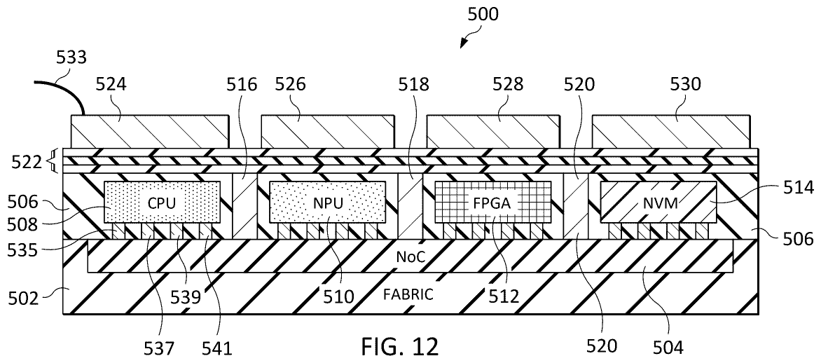

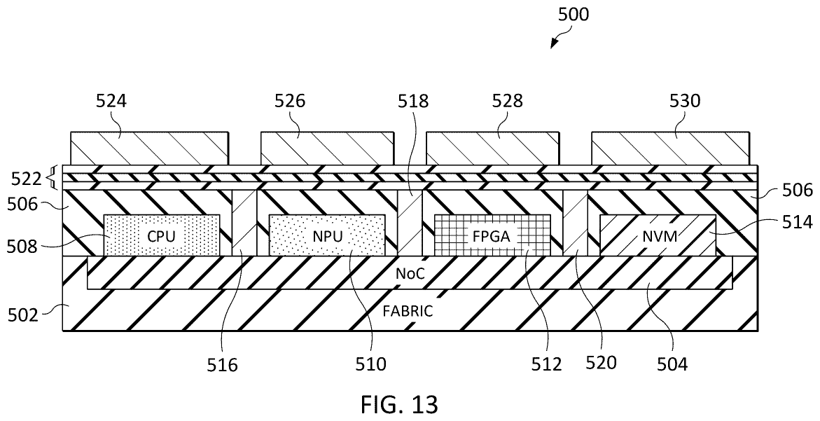

In general, the configurations of FIGS. 12-15 position power delivery modules in close proximity to corresponding circuits (e.g., chiplets) consuming power delivered by the power delivery modules. Referring to FIGS. 12, 3D integrated circuit device 500 includes fabric device 502, which includes network-on-chip 504. In an embodiment, fabric device 502 routes power, signals, or ground to chiplet interface sites. Chiplets 508, 510, 512, and 514 are attached to fabric device 502 using vertical conductors (e.g., microbumps 535, 537, 539, and 541) coupled to chiplet interface sites. In an embodiment, chiplets 508, 510, 512, and 514 are attached to chiplet interface sites of N×M chiplet interface sites of fabric device 502. TMVs 516, 518, and 520 are attached to lanes between the N×M chiplet interface sites of fabric device 502. Mold material 506 includes TMVs 516, 518, and 520, which are coupled to one or more of power delivery modules 524, 526, 528, and 530 via conductors in redistribution layer 522. In at least one embodiment, power delivery modules 524, 526, 528, and 530 include DC-DC converters or other power delivery circuits coupled to a power supply via connector 533 and provide power supply voltages suitable for corresponding chiplets 508, 510, 512, and 514. In an embodiment, chiplets 508, 510, 512, and 514 use different power supply voltage levels and power delivery modules 524, 526, 528, and 530 convert a power supply voltage to corresponding voltage levels. In an embodiment, the 3D integrated circuit device does not use fanout packaging techniques and the 3D integrated circuit device has the same width as fabric device 502. In at least one embodiment, rather than using microbumps, 3D integrated circuit device 500 includes chiplets 508, 510, 512, and 514 that are attached to fabric device 502 using hybrid bonds, as illustrated in FIG. 13.

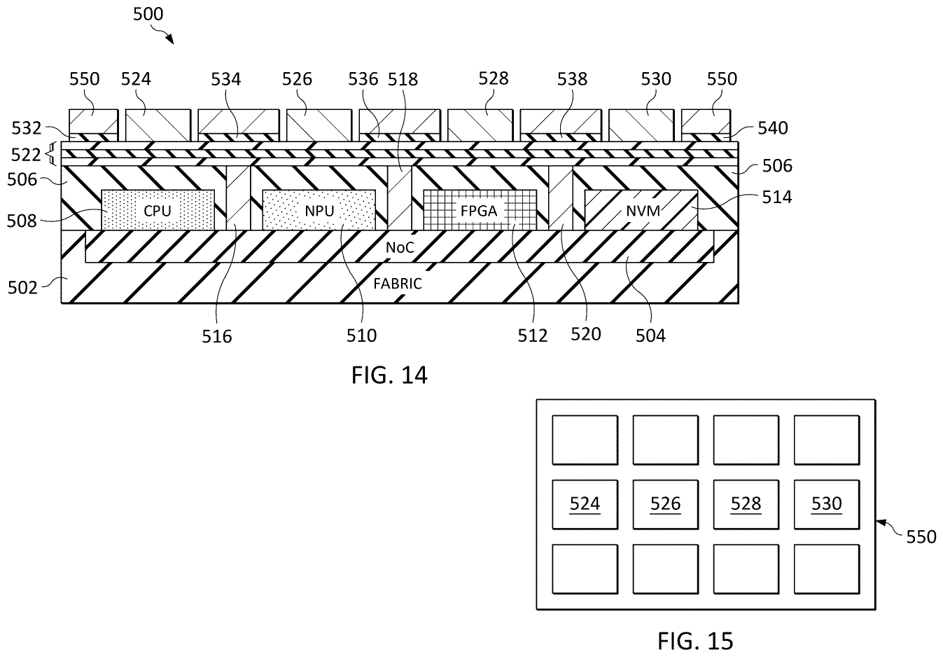

Referring to FIGS. 14 and 15, in at least one embodiment, 3D integrated circuit device 500 includes heat spreader 550 attached to redistribution layer 522 via TIM pockets 532, 534, 536, 538, and 540. In an embodiment heat spreader 550 includes a grid of apertures. In other embodiments, depressions or pockets for holding devices in heat spreader 550 that include openings for conductors are used instead of apertures. Power delivery modules 524, 526, 528, and 530 are disposed in the apertures in the heat spreader 550 and TIM pockets 532, 534, 536, 538, and 540. Heat spreader 550 is made of a thermally conductive material (e.g., copper, diamond, or other thermally conductive material). Although heat spreader 550 has a grid of 3×4 apertures, other configurations of a heat spreader including one or more apertures for attaching an integrated circuit device to a redistribution layer using TIM may be used.

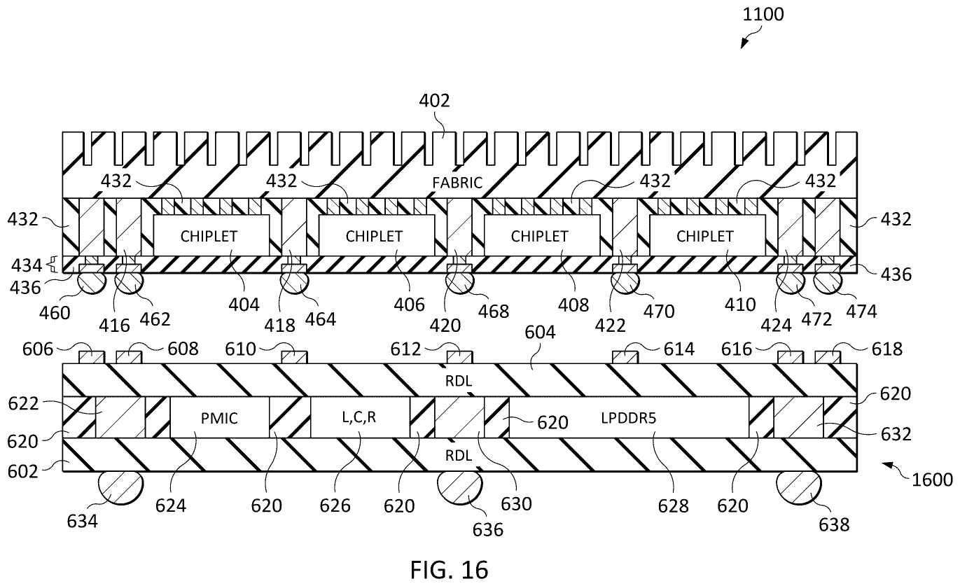

Referring to FIG. 16, in at least one embodiment, 3D integrated circuit device 1100 includes a fabric device that does not use any TSVs. 3D integrated circuit device 1100 is coupled to packaged subsystem 1600 in a Package-on-Package (PoP) configuration with the front side (i.e., face) of the fabric device facing packaged subsystem 1600. Packaged subsystem 1600 includes a subsystem of discrete devices 626 (e.g., passive discrete devices, which may include a capacitor, an inductor, a resistor, or combinations thereof), memory device 628 (e.g., low power DDR5 memory), power management integrated circuit 624, or other integrated circuit devices that are used by a target integrated circuit product. In an embodiment, discrete devices 626, memory device 628, and power management integrated circuit 624 are encapsulated using mold material 620 between RDL 604 and RDL 602. Conductive bumps 634, 636, and 638 are coupled to conductors (not shown) in RDL 602, which are coupled to discrete devices 626, memory device 628, and power management integrated circuit 624. Conductive pads 606, 608, 610, 612, 614, 616, and 618 are coupled to conductors (not shown) in RDL 604, which are coupled to discrete devices 626, memory device 628, and power management integrated circuit 624. Through-mold vias 622, 630, and 632 couple power, signals, or ground between a printed circuit board and 3D integrated circuit device 1100 using RDL 602 and RDL 604. Packaged subsystem 1600 may be one of various packaged subsystems that are compatible with 3D integrated circuit device 1100 and is selected according to the target application. Packaged subsystem 1600 provides power, signals, or ground to 3D integrated circuit device 1100 using through-mold vias 622, 630, and 632 and conductive bumps 634, 636, and 638. Conductive bumps 460, 462, 464, 468, 470, 472, and 474 of 3D integrated circuit device 1100 couple to conductive pads 606, 608, 610, 612, 614, 616, and 618, respectively (e.g., using reflow soldering) to provide power, signals, or ground to 3D integrated circuit device 1100 from packaged subsystem 1600. In an embodiment of the configuration of FIG. 16, an integrated circuit device (e.g., power management integrated circuit 624 or memory device 628) or a discrete device is positioned in close proximity to a corresponding chiplet that provides or consumes a signal consumed or provided by the integrated circuit device or discrete device.

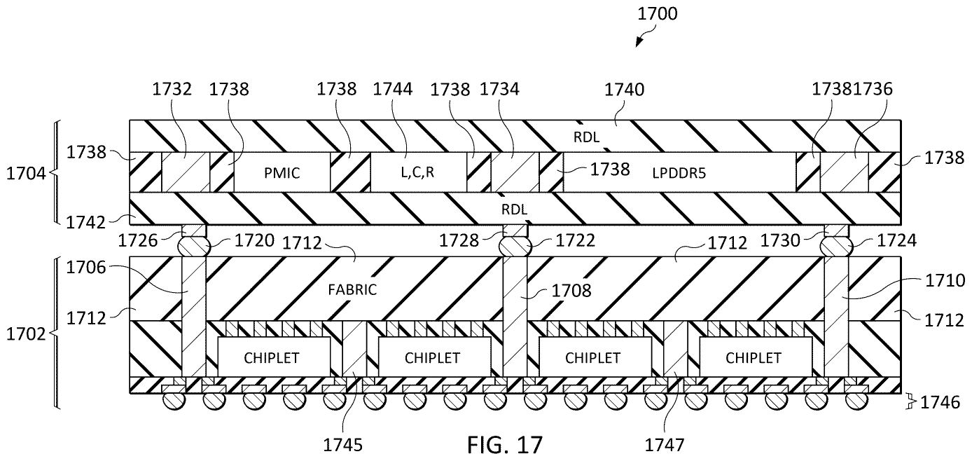

Referring to FIG. 17, in at least one embodiment, TSVs are used for providing power, signals, or ground to a package-on-package and TMVs are used to providing power, signals, or ground to components within a 3D integrated circuit device coupled to the packaged subsystem. For example, package-on-Package (PoP) module 1700 includes 3D integrated circuit device 1702 coupled with the back side of fabric device 1712 facing packaged subsystem 1704. 3D integrated circuit device 1702 includes a fabric device using TSVs used to provide power, signals, or ground to packaged subsystem 1704. For example, TMVs and TSVs 1706, 1708, and 1710 are used to couple power, signals, or ground from ball array 1746 to packaged subsystem 1704 via conductive bumps 1720, 1722, and 1724, and vertical conductors 1726, 1728, and 1730, to RDL 1742. RDL 1742 provides those signals to devices (e.g., discrete devices 1744 or power module or memory in mold material 1738) of the encapsulated subsystem using TMVs 1732, 1734, and 1736, and RDL 1740. Through-mold vias 1745 and 1747 are formed using conductive pillars disposed on fabric device 1712 and disposed in lanes between tiles of an N-by-M tile map of chiplet interface sites to provide power, signals, or ground to fabric device 1712.

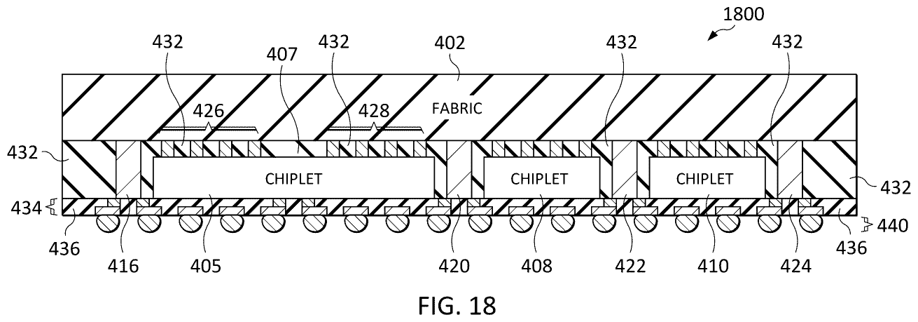

In at least one embodiment of a 3D packaged integrated circuit product, the chiplets have varying discrete sizes that correspond to integer multiples of a unit size chiplet interface and have total sizes of approximately integer multiples of that unit size (to include spacing between chiplet interfaces). Accordingly, chiplets of any combination of the discrete sizes of modular chiplet system can be arranged on a fabric device separated by predetermined space and are coupled to one or more corresponding chiplet interfaces of the fabric device. To accommodate a chiplet that has a discrete size larger than the unit size chiplet interface, one or more conductive pillars are omitted from lanes over which that chiplet is disposed. For example, FIG. 18 includes chiplet 405, which has a discrete size having approximately twice the width of chiplet 408. Chiplet 405 extends across region 407, which corresponds to a lane between vertical conductive structures 426 and 428 that couple to corresponding chiplet interfaces of fabric device 402. A conductive pillar is omitted from region 407 of integrated circuit unit 1800 and is omitted from intermediate structures that occur during manufacture of integrated circuit unit 1800 (e.g., omitted from intermediate structures that correspond to the steps illustrated in FIGS. 4-8).

Thus, embodiments of a 3D packaged modular chiplet system have been described. The description of the invention set forth herein is illustrative and is not intended to limit the scope of the invention as set forth in the following claims. For example, while the invention has been described in an embodiment in which chiplets are attached to a fabric device and conductive pillars between the chiplets being formed on the fabric device, one of skill in the art will appreciate that the teachings herein can be utilized with other integrated circuit die being attached to another type of active semiconductor device and conductive pillars being formed on the active semiconductor device. The terms “first,” “second,” “third,” and so forth, as used in the claims, unless otherwise clear by context, are to distinguish between different items in the claims and do not otherwise indicate or imply any order in time, location, or quality. For example, “a first received signal” and “a second received signal,” do not indicate or imply that the first received signal occurs in time before the second received signal. Variations and modifications of the embodiments disclosed herein may be made based on the description set forth herein, without departing from the scope of the invention as set forth in the following claims.

What is claimed is:

1. An integrated circuit product comprising:
an active semiconductor device comprising a plurality of die interfaces arranged in an N-by-M tile map on a front side of the active semiconductor device, wherein N and M are integers of at least one;
a conductive pillar coupled to the active semiconductor device, disposed on the front side of the active semiconductor device, and extending vertically from the front side of the active semiconductor device;
an integrated circuit die coupled to the front side of the active semiconductor device, the integrated circuit die being disposed face-to-face with the active semiconductor device and being disposed laterally from the conductive pillar with respect to the front side of the active semiconductor device; and
encapsulant disposed on the active semiconductor device, a portion of the encapsulant being disposed between the conductive pillar and the integrated circuit die,
wherein the conductive pillar is disposed on a lane between adjacent die interfaces of the plurality of die interfaces and the conductive pillar is adjacent to the integrated circuit die.

2. The integrated circuit product as recited in claim 1 wherein the integrated circuit die is coupled to a first die interface of the plurality of die interfaces and the integrated circuit product further comprises:
a second integrated circuit die disposed face-to-face with the active semiconductor device, disposed laterally from the integrated circuit die with respect to the front side of the active semiconductor device, and coupled to a second die interface of the plurality of die interfaces; and
at least one additional conductive pillar disposed on another lane of the N-by-M tile map and coupled to the active semiconductor device,
wherein the integrated circuit die and the second integrated circuit die are disposed on adjacent tiles of the N-by-M tile map and the conductive pillar is disposed between the integrated circuit die and the second integrated circuit die.

3. The integrated circuit product as recited in claim 1
wherein the conductive pillar is disposed between the active semiconductor device and a redistribution layer, and
wherein the integrated circuit die and the active semiconductor device do not include any through-silicon vias.

4. The integrated circuit product as recited in claim 1 further comprising:
a redistribution layer disposed on the encapsulant and overlapping the integrated circuit die and the conductive pillar, the redistribution layer including a conductor coupled to the conductive pillar and including dielectric material,
wherein the conductor is coupled to the conductive pillar at a first surface of the redistribution layer and is coupled to a conductive bump at a second surface of the redistribution layer, the second surface being distant from the conductive pillar, the integrated circuit die, and the encapsulant.

5. The integrated circuit product as recited in claim 4 further comprising:
a heat spreader disposed on the redistribution layer, the heat spreader including a grid of apertures; and
at least one integrated circuit module coupled to the conductive pillar and disposed on the redistribution layer and in an aperture of the grid of apertures.

6. The integrated circuit product as recited in claim 1 further comprising:
a packaged circuit subsystem disposed adjacent to a back side of the integrated circuit die, the packaged circuit subsystem comprising a vertical conductive structure coupled to the conductive pillar.

7. The integrated circuit product as recited in claim 1 further comprising:
a through-mold via disposed adjacent to a stack including the active semiconductor device and the integrated circuit die;
a redistribution layer including dielectric material and including conductive traces coupled to the conductive pillar and the through-mold via; and
a packaged integrated circuit device adjacent to a back side of the active semiconductor device and coupled to the through-mold via and the redistribution layer by way of the through-mold via,
wherein a first exposed conductor portion of the through-mold via is coupled to the redistribution layer.

8. The integrated circuit product as recited in claim 1 wherein the integrated circuit product is packaged and has a first width equal to a second width of the active semiconductor device.

9. The integrated circuit product as recited in claim 1 wherein the active semiconductor device comprises:
a network-on-chip,
wherein the plurality of die interfaces are coupled to the network-on-chip.

10. A method of manufacturing an integrated circuit product comprising:
forming a conductive pillar on a front side of an active semiconductor device;
attaching a first integrated circuit die to the front side of the active semiconductor device, the first integrated circuit die being disposed face-to-face with the active semiconductor device and disposed laterally from the conductive pillar with respect to the front side of the active semiconductor device; and
encapsulating the conductive pillar and the first integrated circuit die using encapsulant,
wherein the conductive pillar is formed on a lane separating adjacent die interfaces of a plurality of die interfaces arranged in an N-by-M tile map of a surface of the active semiconductor device, wherein N and M are integers of at least one.

11. The method as recited in claim 10 further comprising:
attaching a second integrated circuit die to the front side of the active semiconductor device, the conductive pillar being between the first integrated circuit die and the second integrated circuit die,
wherein the first integrated circuit die is attached to a first die interface of the plurality of die interfaces and the second integrated circuit die is attached to a second die interface of the plurality of die interfaces.

12. The method as recited in claim 11 further comprising:
exposing an end surface of the conductive pillar; and
forming a redistribution layer on the encapsulant and an exposed end surface of the conductive pillar,
wherein the redistribution layer includes dielectric material and a conductor coupled to the conductive pillar, and
wherein the first integrated circuit die, the second integrated circuit die, and the active semiconductor device do not include any through-silicon vias.

13. The method as recited in claim 12 further comprising:
attaching a heat spreader disposed on the redistribution layer, the heat spreader including a grid of apertures; and
attaching an integrated circuit module to the conductor, the integrated circuit module being disposed on the redistribution layer and disposed in an aperture of the grid of apertures.

14. The method as recited in claim 12 further comprising:
forming a conductive bump on a surface of the redistribution layer and coupled to the conductive pillar;
singulating the integrated circuit product; and
attaching a packaged integrated circuit product to the conductive bump.

15. The method as recited in claim 11 further comprising:
exposing the conductive pillar;
forming a through-mold via disposed adjacent to a stack of devices, the stack of devices including the active semiconductor device, the first integrated circuit die, and the second integrated circuit die; and
forming a redistribution layer including dielectric material and conductive traces coupled to the conductive pillar and the through-mold via,
wherein the first integrated circuit die, the second integrated circuit die, and the active semiconductor device do not include any through-silicon vias.

16. The method as recited in claim 15 further comprising:
attaching a packaged integrated circuit device to a back side of the active semiconductor device and coupled to the through-mold via and the redistribution layer by way of the through-mold via.

17. The method as recited in claim 10 further comprising:
increasing a surface area of a back side of the active semiconductor device.

18. The method as recited in claim 10 further comprising:
selectively exposing through-silicon vias in the active semiconductor device according to a target packaging configuration.

19. An integrated circuit product comprising:
a packaged module comprising:
an active semiconductor device;
a plurality of integrated circuit die coupled to the active semiconductor device using a corresponding plurality of integrated circuit die interfaces; and
a plurality of conductive pillars coupled to the active semiconductor device and disposed on a front side of the active semiconductor device,
wherein the plurality of integrated circuit die interfaces are arranged in an N-by-M tile map on the front side of the active semiconductor device,
wherein N and M are integers of at least one, and
wherein the plurality of conductive pillars are disposed in lanes between tiles of the N-by-M tile map.

20. The integrated circuit product as recited in claim 19 further comprising:
a package-on-package comprising:
a plurality of connectors disposed to align with the lanes between tiles of the N-by-M tile map;
through-mold vias and a plurality of heterogeneous devices disposed laterally with respect to the front side of the active semiconductor device and disposed between a first redistribution layer and a second redistribution layer; and
vertical conductive structures on a first surface of the first redistribution layer, the vertical conductive structures being aligned with the plurality of connectors,
wherein a second surface of the first redistribution layer is closer to the plurality of heterogeneous devices than the first surface.
